(19) United States
(12) Patent Application Publication
(10) Pub. No.: US 2026/0231456 A1
(43) Pub. Date: Aug. 6, 2026

(54) Method of Processing Substrates and Semiconductor Assemblies Having Wide Bandgap Materials

(71) Applicant: Applied Materials, Inc., Santa Clara, CA (US)

(72) Inventor: Amirhasan NOURBAKHSH, Albany, NY (US)

(21) Appl. No.: 19/042,336

(22) Filed: Jan. 31, 2025

(51) Int. Cl. H10D 30/01; H01L 21/762; H10D 30/66; H10D 62/82

(52) U.S. Cl. CPC H10D 30/0291; H10D 30/66; H10D 62/82; H10P 90/1914; H10W 10/181

(57) ABSTRACT

Methods for processing a semiconductor substrate are disclosed herein which include bonding to a silicon layer to a wide bandgap semiconductor layer through a dielectric layer, wherein the dielectric layer is bonded to at least one of the silicon layer or the wide bandgap semiconductor layer by a wafer-to-wafer or a die-to-wafer bonding process. Semiconductor assemblies are also disclosed herein.

### FIELD

Embodiments of the present disclosure generally relate to methods of processing semiconductor substrates, and semiconductor assemblies produced according to methods disclosed herein.

### BACKGROUND

A typical bandgap for silicon is around 1.1 V. The incorporation of wide bandgap materials, e.g., silicon carbide having a bandgap of 3.25 V and gallium nitride having a bandgap of 3.49 V increases the efficiency of numerous semiconductor devices. Examples of how wide bandgap materials increase efficiency include reducing switching time of power metal oxide semiconductor field effect transformers (MOSFETs), and the ability of wide bandgap materials to function at increased voltages for a particular dimension relative to silicon semiconductors. Wide bandgap materials such as silicon carbide also have higher thermal conductivity relative to silicon, and thus conduct heat better than non-wide bandgap material semiconductors. For example, silicon has a thermal conductivity on the order of 1.5 W/cm° C., whereas silicon carbide has a thermal conductivity on the order of 4.5 W/cm° C.

A wide bandgap semiconductor is able to function within a much higher voltage range and at a higher current for a given size, relative to a silicon or other non-wide bandgap material semiconductor. Likewise, the size required by a semiconductor device which includes wide bandgap materials may be reduced for a given voltage or current range relative to a comparable silicon semiconductor.

However, bonding of silicon, e.g., single crystal film directly to a wide bandgap material such as silicon carbide remains elusive due to the lattice mismatch between silicon, having a cubic crystalline structure and silicon carbide having a hexagonal crystalline structure. The relatively large lattice mismatch between silicon and silicon carbide results in relatively high interface stress, defects in various trap states in bonding, and a relatively high interface resistance due to conduction band offset.

### SUMMARY

Methods and apparatus for processing a semiconductor substrate, and semiconductor assemblies are provided herein. In some embodiments, a method of processing a semiconductor substrate, comprises depositing a dielectric layer on a wide bandgap semiconductor layer; forming a via contact through the dielectric layer; and bonding a silicon layer to the dielectric layer by a wafer-to-wafer or a die-to-wafer bonding process, wherein the silicon layer is in electrical connection with the wide bandgap semiconductor layer through the via contact. The proposed method enables the fabrication of a vertical power MOSFET with a silicon channel and wide bandgap (e.g., SiC) drift region. Connectivity is achieved through the via contact using doped polysilicon or metal interconnects embedded in or disposed through the dielectric layer (e.g., SiO₂). The aforementioned design leverages silicon high channel mobility compared to wide bandgap semiconductors for reduced MOSFET output resistance while maintaining high blocking voltage due to the wide bandgap drift region. The inventors have discovered that the Si/SiC configuration surpasses Drain-Source On-Resistance (Rds(on)) limitations of standard SiC power MOSFETs, which are constrained by the high channel resistance of SiC.

In embodiments, a method of processing a semiconductor substrate, comprises depositing a dielectric layer on a silicon layer; forming a via contact through the dielectric layer; and bonding a wide bandgap semiconductor layer to the dielectric layer by a wafer-to-wafer or a die-to-wafer bonding process, wherein the silicon layer is in electrical connection with the wide bandgap semiconductor layer through the via contact.

In embodiments, a semiconductor assembly comprises a dielectric layer disposed between a silicon layer and a wide bandgap semiconductor layer, wherein the silicon layer is bonded to the dielectric layer using at least one of wafer-to-wafer bonding or die-to-wafer bonding; and wherein the silicon layer is in electrical connection with the wide bandgap semiconductor layer through a via contact disposed through the dielectric layer.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A depicts a semiconductor assembly prior to bonding according to embodiments disclosed herein.

FIG. 1B depicts a semiconductor assembly prior to bonding according to other embodiments disclosed herein.

FIG. 2 depicts the semiconductor assembly shown in FIGS. 1A and 1B.

FIG. 3A depicts a wide bandgap layer disposed on a n-doped silicon carbide substrate.

FIG. 3B depicts the substrate shown in FIG. 3A, further processed to include SiC p-well implants.

FIG. 3C depicts the substrate shown in FIG. 3B, further processed to include an n+ contact implant.

FIG. 3D depicts the substrate shown in FIG. 3C, wherein a dielectric layer has been deposited directly onto the wide bandgap layer.

FIG. 3E depicts the substrate shown in FIG. 3D, further processed to include a via contact through the dielectric layer.

FIG. 3F depicts the substrate shown in FIG. 3E, wherein a silicon layer has been bonded directly onto the dielectric layer via wafer-to-wafer bonding or die-to-wafer bonding.

FIG. 3G depicts the substrate shown in FIG. 3F, further processed to include a silicon p-well implant.

FIG. 3H depicts the substrate shown in FIG. 3G, further processed to include n+ source implants.

FIG. 3I depicts the substrate shown in FIG. 3H, further processed to include vias etched through the silicon and dielectric layers into a portion of the wide bandgap layer.

FIG. 3J depicts the substrate shown in FIG. 3I, further processed to fill the vias show in FIG. 3I.

FIG. 3K depicts the substrate shown in FIG. 3J, further processed to include a gate and gate oxide layer.

FIG. 3L depicts the substrate shown in FIG. 3K, further processed to include metallization layers thus completing a MOSFET semiconductor assembly according to embodiments disclosed herein.

FIG. 4A depicts a wafer comprising a plurality of substrates comprising a wide bandgap layer according to embodiments disclosed herein.

FIG. 4B depicts the wafer comprising the plurality of substrates shown in FIG. 4A, further processed to fill gaps between the plurality of substrates with a dielectric layer.

FIG. 4C depicts the wafer comprising the plurality of substrates shown in FIG. 4B, in which the dielectric layer has been further processed via planarization.

FIG. 4D depicts the wafer comprising the plurality of substrates shown in FIG. 4C, wherein a dielectric layer has been deposited on wide bandgap layer, and the deposited dielectric layer has been processed to include a plurality of via contacts disposed through the dielectric layer comprising doped polysilicon.

FIG. 4E depicts the wafer comprising the plurality of substrates shown in FIG. 4D, wherein a polysilicon layer has been bonded directly onto the dielectric layer via wafer-to-wafer bonding.

FIG. 4F depicts the wafer comprising the plurality of substrates shown in FIG. 4E, further processed to include various features.

FIG. 4G depicts the wafer comprising the plurality of substrates shown in FIG. 4F, further processed to include metallization layers thus completing a plurality of MOSFET semiconductor assemblies disposed on the wafer.

FIG. 4H depicts the dicing of the wafer comprising the plurality of substrates shown in FIG. 4G, to produce a plurality of MOSFET semiconductor assemblies according to embodiments disclosed herein.

FIG. 5 depicts a method of processing a substrate according to embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods for processing a semiconductor substrate having a wide bandgap material are provided herein, along with semiconductor assemblies comprising wide bandgap materials, which are produced according to embodiments of the methods disclosed herein.

In embodiments, unless otherwise indicated, one or more of the various layers of the semiconductor assembly may further include dopants, e.g., n-dopants, p-dopants, and the like, which may may be infused, implanted, or otherwise enriched within the layer. For example, unless otherwise specified, disclosure of a silicon layer includes an undoped or doped silicon or polysilicon layer. Likewise, unless otherwise specified, disclosure of a wide bandgap layer may include either an undoped or doped layer.

For purposes herein, the bonding of two layers together refers to contacting surfaces of the two layers under conditions sufficient to produce a bond therebetween. Suitable bonding conditions may include increased temperature and pressure being applied for a period of time sufficient to form a high-quality fusion bond between the two layers.

As used herein, a wide-bandgap semiconductor refers to a semiconductor material having a larger band gap than more conventional semiconductors such as silicon and selenium. For example, conventional semiconductors silicon and selenium have a bandgap in the range of 0.7-1.5 electronvolt (eV), whereas wide-bandgap semiconductor materials have bandgaps which exceed 1.5 eV, and which may exceed 2 eV. One example of a wide bandgap semiconductor is silicon carbide, which has a bandgap from about 2.3 eV to 3.3 eV depending on the crystalline structure of the material.

In embodiments, a method of processing a semiconductor substrate, comprises depositing a dielectric layer on a wide bandgap semiconductor layer; forming a via contact through the dielectric layer; and bonding a silicon layer to the dielectric layer by a wafer-to-wafer or a die-to-wafer bonding process, wherein the silicon layer is in electrical connection with the wide bandgap semiconductor layer through the via contact.

In embodiments, the via contact comprises, consists essentially of, or consists of doped polysilicon. In embodiments, the via contact comprises, consists essentially of, or consists of a metal. In embodiments, the via contact is an ohmic contact.

In embodiments, the wide bandgap semiconductor layer comprises, consists essentially of, or consists of silicon carbide, boron nitride, gallium nitride, aluminum nitride, gallium arsenide, aluminum arsenide, aluminum phosphide, gallium phosphide, cadmium sulfide, zinc sulfide, or a combination thereof. In embodiments, the silicon layer comprises, consists essentially of, or consists of polysilicon. In embodiments, the dielectric layer comprises, consists essentially of, or consists of silicon oxide.

In embodiments, the method further includes doping or implanting one or more portions of the wide bandgap semiconductor layer prior to the dielectric layer being formed on the wide bandgap semiconductor layer. In embodiments, the method includes doping or implanting one or more portions of the silicon layer prior to bonding the silicon layer to the dielectric layer. In embodiments, the method further includes doping or implanting one or more portions of the silicon layer after bonding the silicon layer to the dielectric layer. In embodiments, the method includes forming one or more features disposed through the silicon layer, the dielectric layer, and into a portion of the wide bandgap semiconductor layer.

In embodiments, a method of processing a semiconductor substrate, comprises doping or implanting portions of an upper surface of the wide bandgap semiconductor layer, wherein the wide bandgap semiconductor layer comprises silicon carbide, boron nitride, gallium nitride, aluminum nitride, gallium arsenide, aluminum arsenide, aluminum phosphide, gallium phosphide, cadmium sulfide, zinc sulfide, or a combination thereof; forming a dielectric layer comprising silicon oxide on an upper surface of the wide bandgap semiconductor layer; forming a via contact through the dielectric layer comprising doped polysilicon; and bonding a lower face of a silicon layer to an upper face of the dielectric layer using at least one of wafer-to-wafer bonding or die-to-wafer bonding; wherein the silicon layer is in electrical connection with the wide bandgap semiconductor layer through the via contact.

In some embodiments, the method includes forming one or more features disposed through the polysilicon layer, the dielectric layer, and into a portion of the wide bandgap semiconductor layer. In some embodiments, the method further comprises doping or implanting one or more portions of the silicon layer prior to bonding the lower face of the silicon layer to the upper face of the dielectric layer. In some embodiments, the method further comprises doping or implanting one or more portions of the silicon layer after bonding the lower face of the silicon layer to the upper face of the dielectric layer.

In embodiments, a method of processing a semiconductor substrate, comprises depositing a dielectric layer on a silicon layer; forming a via contact through the dielectric layer; and bonding a wide bandgap semiconductor layer to the dielectric layer by a wafer-to-wafer or a die-to-wafer bonding process, wherein the silicon layer is in electrical connection with the wide bandgap semiconductor layer through the via contact. In some embodiments, the wide bandgap semiconductor layer comprises silicon carbide, boron nitride, gallium nitride, aluminum nitride, gallium arsenide, aluminum arsenide, aluminum phosphide, gallium phosphide, cadmium sulfide, zinc sulfide, or a combination thereof.

In embodiments, the method further includes doping or implanting one or more portions of the silicon layer, the wide bandgap semiconductor layer, or both, prior to and/or after bonding a lower face of the wide bandgap semiconductor layer to an upper face of the dielectric layer. In embodiments, the method further includes forming one or more features disposed through the silicon layer, the dielectric layer, and into a portion of the wide bandgap semiconductor layer.

In embodiments, a plurality of the semiconductor substrates are each processed, on a single support substrate, to form a plurality of processed substrates; the method further comprises separating each of the processed substrates from the single support substrate after bonding the lower face of the silicon layer to the upper face of the dielectric layer, or after bonding the lower face of the wide bandgap semiconductor layer to the upper face of the dielectric layer. In some embodiments, the method includes disposing a dielectric fill layer between each of the substrates disposed on the single support substrate prior to depositing the dielectric layer onto the wide bandgap semiconductor layer, followed by bonding the lower face of the silicon layer to the upper face of the dielectric layer using at least one of wafer-to-wafer bonding or die-to-wafer bonding.

In some embodiments, the method includes disposing a dielectric fill layer between each of the substrates disposed on the single support substrate prior to depositing the dielectric layer onto the silicon layer, followed by bonding the lower face of the wide bandgap semiconductor layer to the upper face of the dielectric layer using at least one of wafer-to-wafer bonding or die-to-wafer bonding.

In embodiments, a semiconductor assembly comprises a dielectric layer disposed between a silicon layer and a wide bandgap semiconductor layer, wherein the silicon layer is bonded to the dielectric layer or wherein the wide bandgap semiconductor layer is bonded to the dielectric layer, using at least one of wafer-to-wafer bonding or die-to-wafer bonding; and wherein the silicon layer is in electrical connection with the wide bandgap semiconductor layer through a via contact disposed through the dielectric layer. In embodiments of the semiconductor assembly, the wide bandgap semiconductor layer comprises silicon carbide, boron nitride, gallium nitride, aluminum nitride, gallium arsenide, aluminum arsenide, aluminum phosphide, gallium phosphide, cadmium sulfide, zinc sulfide, or a combination thereof; the silicon layer comprises polysilicon; and the dielectric layer comprises silicon oxide. In embodiments, the semiconductor assembly is configured as a power MOSFET, which in embodiments is a vertical power MOSFET.

Silicon has a cubic crystalline structure. In contrast, wide bandgap materials such as silicon carbide have a hexagonal crystalline structure. As a result, a large e.g., significant, lattice mismatch of over 40% exists between a silicon layer, e.g., polysilicon, deposited on a silicon carbide layer as well as other wide bandgap materials. As a result of the lattice mismatch, forming of layers of silicon layers, e.g., via deposition, directly onto silicon carbide results in relatively high interfacial stress between the two layers, as well as the formation of various defects and trap states between the two layers.

Silicon offers relatively high channel mobility and & relativity superior gate oxide stability over silicon carbide. By comparison, silicon carbide has relatively low channel mobility, yet offers relatively high breakdown field characteristics.

The inventors have discovered that the issues associated with direct formation of a silicon layer on a high bandgap layer such as silicon carbide can be mitigated by deposition of a dielectric layer on the high bandgap layer, followed by wafer-to-wafer or die-to-wafer bonding, e.g., fusion bonding, of a silicon layer onto the dielectric layer. Processing of the dielectric layer prior to bonding of the silicon layer to form a via connect disposed through the dielectric layer has been observed to provide electrical conductivity between the silicon layer and the wide bandgap layer, thus providing the above benefits of the two materials, i.e., the benefit of silicon layer and the benefit of the silicon carbide layer, and mitigating the issues from depositing the silicon layer directly onto the silicon carbide layer discussed above.

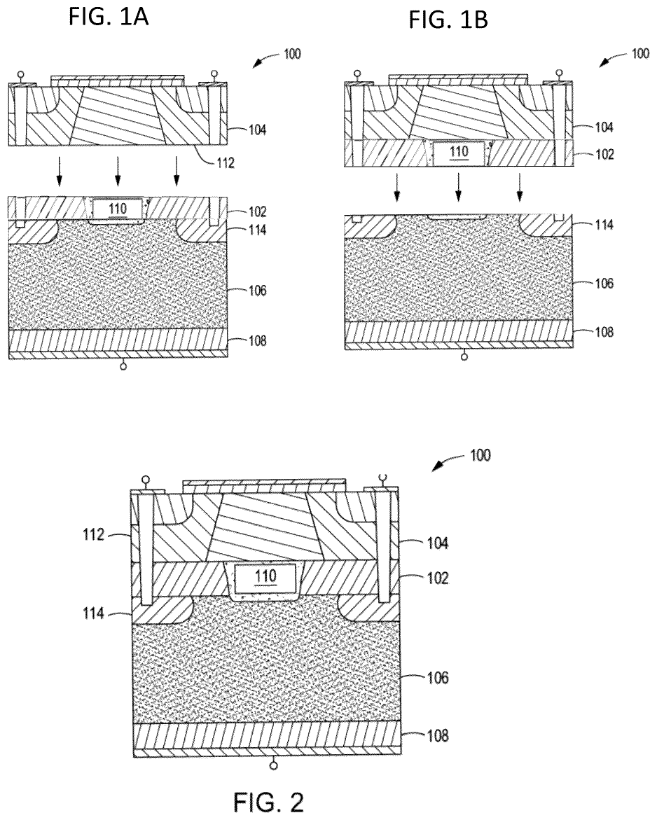

FIG. 1A depicts an exploded view of a semiconductor assembly according to embodiments disclosed herein. FIG. 1B depicts an exploded view of a semiconductor assembly according to other embodiments disclosed herein. FIG. 2 depicts the semiconductor assembly shown in FIGS. 1A and 1B. As shown in FIG. 1A, the semiconductor assembly 100 comprises a dielectric layer 102 disposed between a silicon layer 104 and a wide bandgap semiconductor layer 106 disposed on a substrate 108. The dielectric layer 102 is formed on the wide bandgap semiconductor layer 106 by a deposition process, e.g., PVD, CVD, ALD, plasma assisted variants thereof, and/or the like, and the silicon layer 104 is bonded to the dielectric layer 102 using at least one of wafer-to-wafer bonding or die-to-wafer bonding, e.g., a fusion bonding process, which in embodiments includes an elevated temperature fusion bonding process.

As shown in FIG. 1B, the semiconductor assembly 100 comprises a dielectric layer 102 disposed between a silicon layer 104 and a wide bandgap semiconductor layer 106 disposed on a substrate 108. The dielectric layer 102 is formed on the silicon layer 104 by a deposition process, e.g., PVD, CVD, ALD, plasma assisted variants thereof, and/or the like, and the wide bandgap semiconductor layer 106 is bonded to the dielectric layer 102 using at least one of wafer-to-wafer bonding or die-to-wafer bonding, e.g., a fusion bonding process, which in embodiments includes an elevated temperature fusion bonding process.

As shown in FIGS. 1A, 1B, and 2, the dielectric layer 102, the silicon layer 104 and the wide bandgap semiconductor layer 106 may further include various features dopants, and regions according to an intended purpose of the resultant semiconductor assembly. In embodiments, the intended purpose of the resultant semiconductor assembly is as a power MOSFET. Likewise, the substrate 108 may further include various features e.g., metal contacts, and additional layers as required by the semiconductor assembly.

As shown in FIG. 2, in embodiments, the silicon layer 104 is in electrical connection with the wide bandgap semiconductor layer 106 by a through-via, i.e., a via connect 110 disposed through the dielectric layer 102. In embodiments, the via connect 110 comprises doped polysilicon, or a metal. In embodiments, the via connect 110 is an ohmic contact.

In embodiments, the silicon layer 104 comprises, consists essentially of, or consists of polysilicon. In embodiments, one or more portions or regions 112 of the wide bandgap semiconductor layer 106 each individually include dopants, e.g., p dopants, n+dopants and the like.

In embodiments, the wide bandgap semiconductor layer 106 comprises, consists essentially of, or consists of silicon carbide, boron nitride, gallium nitride, aluminum nitride, gallium arsenide, aluminum arsenide, aluminum phosphide, gallium phosphide, cadmium sulfide, zinc sulfide, or a combination thereof. In embodiments, one or more portions or regions 114 of the wide bandgap semiconductor layer 106 each individually include dopants, e.g., p dopants, n+ dopants, and the like.

In embodiments, the wide bandgap semiconductor layer 106 comprises, consists essentially of, or consists of silicon carbide, gallium nitride, or a combination thereof, portions of which may be doped or undoped.

In embodiments, the dielectric layer comprises a metal oxide, which in embodiments, comprises, consists essentially of, or consists of silicon oxide. In embodiments, any one or more of the dielectric layer 102, the silicon layer 104, and the wide bandgap semiconductor layer 106 may be further processed to include various features e.g., vias, additional layers, doped regions, and the like, prior to, and/or after forming the dielectric layer 102 on the wide bandgap semiconductor layer 106, and/or before or after bonding of the silicon layer 104 to the dielectric layer 102 by a wafer-to-wafer or a die-to-wafer bonding process.

In embodiments, the silicon layer 104 is bonded to the dielectric layer 102 by wafer-to-wafer or a die-to-wafer bonding process, e.g., a fusion bonding process. In embodiments, the dielectric layer 102 is formed directly on the wide bandgap semiconductor layer 106 via a deposition process, e.g., via PVD, CVD, ALD, variants thereof, and any combination thereof.

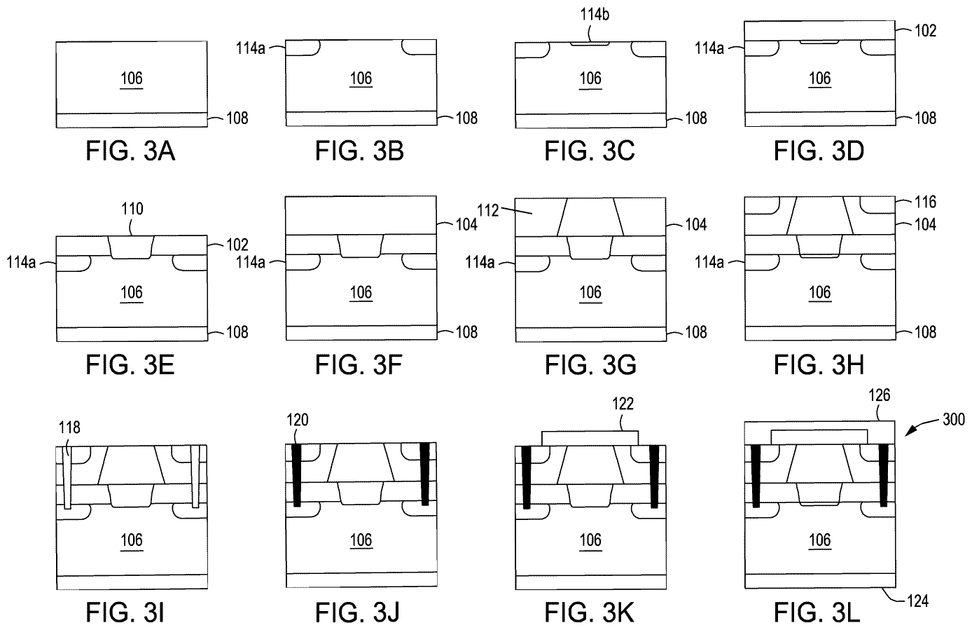

As shown in FIG. 3A through 3L, in embodiments, a method of processing a semiconductor substrate comprises forming dielectric layer 102 on a wide bandgap semiconductor layer 106, and fusion bonding a silicon layer 104 on the dielectric layer 102 by a die-to-wafer fusion bonding process.

As shown in FIG. 3A, in embodiments, a wide bandgap semiconductor layer 106 is disposed on an n-doped silicon carbide substrate 108. As shown in FIGS. 3B and 3C, the substrate may then undergo additional processing. Such additional processing may include forming doped regions and features 114a and 114b. For example, FIG. 3B shows the substrate of FIG. 3A further processed to include SiC p-well implant feature 114a and FIG. 3C shows the substrate of FIG. 3B further processed to include an n+contact implant feature 114b.

A dielectric layer 102 is then formed on the wide bandgap semiconductor layer 106 by a deposition process as shown in FIG. 3D. As shown in FIG. 3E, the dielectric layer 102 is then subject to additional processing, e.g., forming of a via connect 110 comprising polysilicon through the dielectric layer 102, followed by bonding a lower surface of the silicon layer 104 to an upper surface of the dielectric layer 102 by a die-to-wafer fusion bonding process as shown in FIG. 3F.

As shown in FIGS. 3G, 3H, 3I, 3J, 3K, and 3L, the various layers are processed to include other doped regions e.g., 116, vias 118, filled vias 120, additional layers 122, and/or the like, to produce the final semiconductor assembly 300 shown in FIG. 3L, e.g., a vertical power MOSFET. For example: FIG. 3G shows the substrate of FIG. 3F further processed to include a silicon p-well implant region 112. FIG. 3H shows the substrate of FIG. 3G further processed to include n+source implants 116. FIG. 3I shows the substrate of FIG. 3H, further processed to include vias 118 etched through the silicon layer 104, e.g., a polysilicon layer, and the dielectric layer 102. FIG. 3J shows the substrate of FIG. 3I further processed to fill the vias 118 to form filled vias 120 shown in FIG. 3I; FIG. 3K shows the substrate of FIG. 3J further processed to include additional layers 122, e.g., a gate and gate oxide layer; and FIG. 3L shows the substrate of FIG. 3K further processed to include a metallization layer 124, source and body metal layer 126, thus forming a complete semiconductor assembly, e.g., a power MOSFET, according to embodiments disclosed herein.

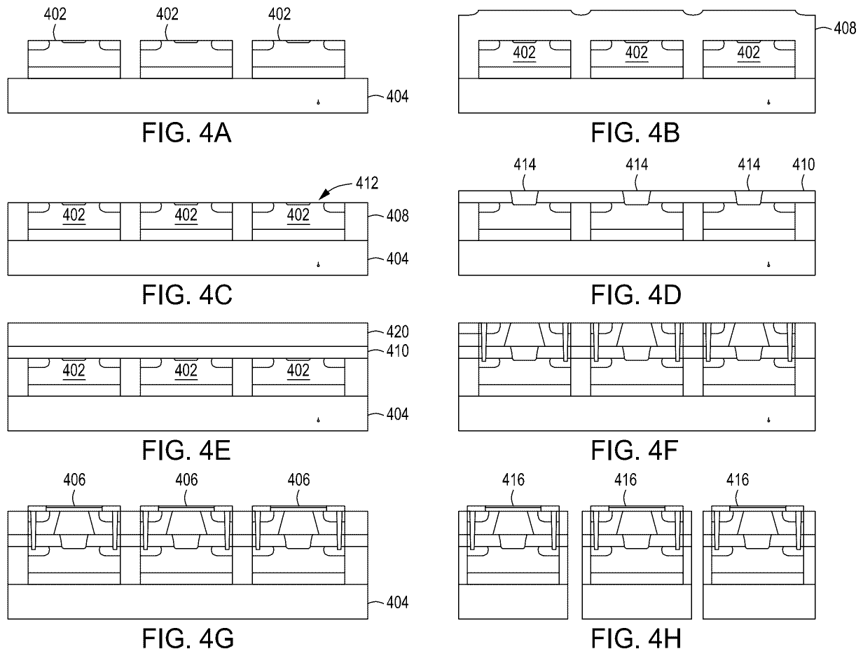

As shown in FIG. 4A through 4H, in embodiments, a plurality of semiconductor substrates, e.g., a plurality of substrates 402 are processed, each disposed on a single support wafer 404 shown in FIG. 4A, to form a plurality of processed semiconductor assemblies 406 shown in FIG. 4G. In embodiments, the method further comprises separating each of the processed substrates from the single support substrate 404 to form a plurality of individual processed substrates 416 as shown in FIG. 4H.

As shown in FIG. 4B, in embodiments, the method further comprises disposing a dielectric fill layer 408 between each of the plurality of substrates 402 disposed on the single support wafer 404, which as shown in FIG. 4C may be further processed via planarization.

FIG. 4D shows the support wafer 404 comprising the plurality of the substrates 402 of FIG. 4C wherein a dielectric layer 410 has been deposited over the plurality of substrates 402 and the dielectric fill layer 408 using a deposition process. The dielectric layer 410 has also been subjected to further processing to comprise a plurality of a via contacts 414 disposed through the dielectric layer 410 comprising doped polysilicon.

FIG. 4E shows the wafer comprising the plurality of the substrates 402 having the dielectric layer 410 shown in FIG. 4D, to which a polysilicon layer 420 has been bonded directly onto the dielectric layer 410 via a wafer-to-wafer fusion bonding process.

FIG. 4F shows the support wafer 404 shown in FIG. 4E after various processing of the substrates to include various features, and FIG. 4G shows the wafer of FIG. 4F, further processed to include metallization layers thus completing a plurality of semiconductor assemblies 406 disposed on the support wafer 404. FIG. 4H shows the dicing e.g., separating of the support wafer 404 comprising the plurality of semiconductor assemblies 406 of FIG. 4G, to produce a plurality of final semiconductor assemblies 416 according to embodiments disclosed herein.

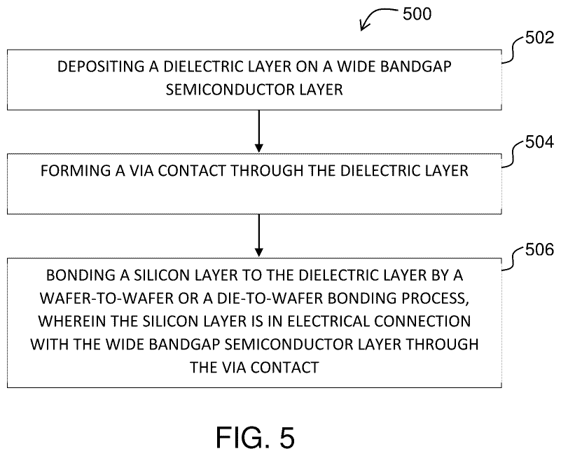

As shown in FIG. 5, in embodiments, a method of processing a semiconductor substrate 500, comprises depositing a dielectric layer on a wide bandgap semiconductor layer (block 502); forming a via contact through the dielectric layer (block 504); and bonding a silicon layer to the dielectric layer by a wafer-to-wafer or a die-to-wafer bonding process, wherein the silicon layer is in electrical connection with the wide bandgap semiconductor layer through the via contact (block 506).

In embodiments, the method of processing a semiconductor substrate 500 may include additional blocks.

Embodiments consistent with the instant disclosure include:
E1. A method of processing a semiconductor substrate, comprising:
   depositing a dielectric layer on a wide bandgap semiconductor layer;
   forming a via contact through the dielectric layer; and
   bonding a silicon layer to the dielectric layer by a wafer-to-wafer or a die-to-wafer bonding process, wherein the silicon layer is in electrical connection with the wide bandgap semiconductor layer through the via contact.
E2. The method according to embodiment E1, wherein the via contact comprises doped polysilicon.
E3. The method according to embodiments E1-E2, wherein the via contact comprises a metal.
E4. The method according to embodiments E1-E3, wherein the via contact is an ohmic contact.
E5. The method according to embodiments E1-E4, wherein the wide bandgap semiconductor layer comprises silicon carbide, boron nitride, gallium nitride, aluminum nitride, gallium arsenide, aluminum arsenide, aluminum phosphide, gallium phosphide, cadmium sulfide, zinc sulfide, or a combination thereof.
E6. The method according to embodiments E1-E5, wherein the silicon layer comprises polysilicon.
E7. The method according to embodiments E1-E6, wherein the dielectric layer comprises silicon oxide.
E8. The method according to embodiments E1-E7, further comprising doping or implanting one or more portions of the wide bandgap semiconductor layer prior to the dielectric layer being formed on the wide bandgap semiconductor layer.
E9. The method according to embodiments E1-E8, further comprising doping or implanting one or more portions of the silicon layer prior to bonding the silicon layer to the dielectric layer.
E10. The method according to embodiments E1-E9, further comprising doping or implanting one or more portions of the silicon layer after bonding the silicon layer to the dielectric layer.
E11. The method according to embodiments E1-E10, further comprising: forming one or more features disposed through the silicon layer, the dielectric layer, and into a portion of the wide bandgap semiconductor layer.
E12. A method of processing a semiconductor substrate, comprising:
   depositing a dielectric layer on a silicon layer;
   forming a via contact through the dielectric layer; and
   bonding a wide bandgap semiconductor layer to the dielectric layer by a wafer-to-wafer or a die-to-wafer bonding process, wherein the silicon layer is in electrical connection with the wide bandgap semiconductor layer through the via contact.
E13. The method according to embodiment E12, wherein the wide bandgap semiconductor layer comprises silicon carbide, boron nitride, gallium nitride, aluminum nitride, gallium arsenide, aluminum arsenide, aluminum phosphide, gallium phosphide, cadmium sulfide, zinc sulfide, or a combination thereof.
E14. The method according to embodiments E12-E13, further comprising doping or implanting one or more portions of the silicon layer, the wide bandgap semiconductor layer, or both, prior to and/or after bonding a lower face of the wide bandgap semiconductor layer to an upper face of the dielectric layer.
E15. The method according to embodiments E12-E14, further comprising:
   forming one or more features disposed through the silicon layer, the dielectric layer, and into a portion of the wide bandgap semiconductor layer.
E16. The method according to embodiments E1-E15, wherein a plurality of the semiconductor substrates are processed, on a single support substrate, to form a plurality of processed substrates, and further comprising separating each of the processed substrates from the single support substrate after bonding the lower face of the silicon layer to the upper face of the dielectric layer, or after bonding the lower face of the wide bandgap semiconductor layer to the upper face or of the dielectric layer.
E17. The method according to embodiments E16, further comprising:
   disposing a dielectric fill layer between each of the substrates disposed on the single support substrate prior to bonding the lower face of the silicon layer to the upper face of the dielectric layer using at least one of wafer-to-wafer bonding or die-to-wafer bonding.
E18. A semiconductor assembly formed according to the method of any one of embodiments E1-E17, comprising:
   a dielectric layer disposed between a silicon layer and a wide bandgap semiconductor layer, wherein the silicon layer is bonded to the dielectric layer using
   at least one of wafer-to-wafer bonding or die-to-wafer bonding, or wherein the wide bandgap semiconductor layer is bonded to the dielectric layer using at least one of wafer-to-wafer bonding or die-to-wafer bonding; and
   wherein the silicon layer is in electrical connection with the wide bandgap semiconductor layer through a via contact disposed through the dielectric layer.
E19. A semiconductor assembly, comprising:
   a dielectric layer disposed between a silicon layer and a wide bandgap semiconductor layer, wherein the silicon layer is bonded to the dielectric layer using at least one of wafer-to-wafer bonding or die-to-wafer bonding, or
   wherein the wide bandgap semiconductor layer is bonded to the dielectric layer using at least one of wafer-to-wafer bonding or die-to-wafer bonding; and
   wherein the silicon layer is in electrical connection with the wide bandgap semiconductor layer through a via contact disposed through the dielectric layer.
E20. The semiconductor assembly according to embodiment E18-E19, wherein the wide bandgap semiconductor layer comprises silicon carbide, boron nitride, gallium nitride, aluminum nitride, gallium arsenide, aluminum arsenide, aluminum phosphide, gallium phosphide, cadmium sulfide, zinc sulfide, or a combination thereof, wherein the silicon layer comprises polysilicon, and wherein the dielectric layer comprises silicon oxide.
E21. A power mosfet semiconductor device comprising the semiconductor assembly of embodiment E18-E20.

While the foregoing is directed to embodiments of the present disclosure, other and further embodiments of the disclosure may be devised without departing from the basic scope thereof.

1. A method of processing a semiconductor substrate, comprising:
depositing a dielectric layer on a wide bandgap semiconductor layer;
forming a via contact through the dielectric layer; and
bonding a silicon layer to the dielectric layer by a wafer-to-wafer or a die-to-wafer bonding process, wherein the silicon layer is in electrical connection with the wide bandgap semiconductor layer through the via contact.

2. The method of claim 1, wherein the via contact comprises doped polysilicon.

3. The method of claim 1, wherein the via contact comprises a metal.

4. The method of claim 1, wherein the via contact is an ohmic contact.

5. The method of claim 1, wherein the wide bandgap semiconductor layer comprises silicon carbide, boron nitride, gallium nitride, aluminum nitride, gallium arsenide, aluminum arsenide, aluminum phosphide, gallium phosphide, cadmium sulfide, zinc sulfide, or a combination thereof.

6. The method of claim 1, wherein the silicon layer comprises polysilicon.

7. The method of claim 1, wherein the dielectric layer comprises silicon oxide.

8. The method of claim 1, further comprising doping or implanting one or more portions of the wide bandgap semiconductor layer prior to the dielectric layer being formed on the wide bandgap semiconductor layer.

9. The method of claim 1, further comprising doping or implanting one or more portions of the silicon layer prior to bonding the silicon layer to the dielectric layer.

10. The method of claim 1, further comprising doping or implanting one or more portions of the silicon layer after bonding the silicon layer to the dielectric layer.

11. The method of claim 1, further comprising:
forming one or more features disposed through the silicon layer, the dielectric layer, and into a portion of the wide bandgap semiconductor layer.

12. A method of processing a semiconductor substrate, comprising:
depositing a dielectric layer on a silicon layer;
forming a via contact through the dielectric layer; and
bonding a wide bandgap semiconductor layer to the dielectric layer by a wafer-to-wafer or a die-to-wafer bonding process, wherein the silicon layer is in electrical connection with the wide bandgap semiconductor layer through the via contact.

13. The method of claim 12, wherein the wide bandgap semiconductor layer comprises silicon carbide, boron nitride, gallium nitride, aluminum nitride, gallium arsenide, aluminum arsenide, aluminum phosphide, gallium phosphide, cadmium sulfide, zinc sulfide, or a combination thereof.

14. The method of claim 12, further comprising doping or implanting one or more portions of the silicon layer, the wide bandgap semiconductor layer, or both, prior to and/or after bonding a lower face of the wide bandgap semiconductor layer to an upper face of the dielectric layer.

15. The method of claim 12, further comprising:
forming one or more features disposed through the silicon layer, the dielectric layer, and into a portion of the wide bandgap semiconductor layer.

16. The method of claim 1, wherein a plurality of the semiconductor substrates are processed, on a single support substrate, to form a plurality of processed substrates, and further comprising separating each of the processed substrates from the single support substrate after bonding a lower face of the silicon layer to an upper face of the dielectric layer.

17. The method of claim 16, further comprising:
disposing a dielectric fill layer between each of the substrates disposed on the single support substrate prior to bonding the lower face of the silicon layer to the upper face of the dielectric layer using at least one of wafer-to-wafer bonding or die-to-wafer bonding.

18. A semiconductor assembly, comprising:
a dielectric layer disposed between a silicon layer and a wide bandgap semiconductor layer, wherein the silicon layer is bonded to the dielectric layer using at least one of wafer-to-wafer bonding or die-to-wafer bonding, or
wherein the wide bandgap semiconductor layer is bonded to the dielectric layer using at least one of wafer-to-wafer bonding or die-to-wafer bonding; and
wherein the silicon layer is in electrical connection with the wide bandgap semiconductor layer through a via contact disposed through the dielectric layer.

19. The semiconductor assembly of claim 18, wherein the wide bandgap semiconductor layer comprises silicon carbide, boron nitride, gallium nitride, aluminum nitride, gallium arsenide, aluminum arsenide, aluminum phosphide, gallium phosphide, cadmium sulfide, zinc sulfide, or a combination thereof, wherein the silicon layer comprises polysilicon, and wherein the dielectric layer comprises silicon oxide.

20. A power mosfet semiconductor device comprising the semiconductor assembly of claim 18.
